(19) United States
(12) Patent Application Publication
(10) Pub. No.: US 2013/0221412 A1
(43) Pub. Date: Aug. 29, 2013

(54) Device System Structure Based On Hybrid Orientation SOI and Channel Stress and Preparation Method Thereof

(71) Applicants: Jiantao Bian, Shanghai (CN); Zengfeng Di, Shanghai (CN); Miao Zhang, Shanghai (CN)

(72) Inventors: Jiantao Bian, Shanghai (CN); Zengfeng Di, Shanghai (CN); Miao Zhang, Shanghai (CN)

(73) Assignee: SHANGHAN INSTITUTE OF MICROSYSTEM AND INFORMATION TECHNOLOGY, CHINESE ACADEMY, Shanghai (CN)

(21) Appl. No.: 13/811,269

(22) PCT Filed: Sep. 19, 2012
(86) PCT No.: PCT/CN12/81599

§ 371 Date: Jan. 19, 2013

(30) Foreign Application Priority Data
Feb. 27, 2012 (CN) 201210046230.2

(51) Int. Cl. H01L 29/04; H01L 29/786; H01L 29/66

(52) U.S. Cl. CPC H01L 29/045; H01L 29/66772; H01L 29/78654
USPC 257/255; 438/150

(57) ABSTRACT

The present invention provides a device system structure based on hybrid orientation SOI and channel stress and a preparation method thereof. According to the preparation method provided in the present invention, first, a (100)/(110) global hybrid orientation SOI structure is prepared; then, after epitaxially growing a relaxed silicon-germanium layer and strained silicon layer sequentially on the global hybrid orientation SOI structure, an (110) epitaxial pattern window is formed; then, after epitaxially growing a (110) silicon layer and a non-relaxed silicon-germanium layer at the (110) epitaxial pattern window, a surface of the patterned hybrid orientation SOI structure is planarized; then, an isolation structure for isolating devices is formed; and finally, a P-type high-voltage device structure is prepared in a (110) substrate portion, an N-type high-voltage device structure and/or low voltage device structures are prepared in the (100) substrate portion. In this manner, a carrier mobility is improved, Rdson of a high-voltage device is reduced, and performance of devices are improved, thereby facilitating further improvement of integration and reduction of power consumption.

### BACKGROUND OF THE PRESENT INVENTION

1. Field of Invention

The present invention relates to the field of semiconductor, and in particular, to a device system structure based on hybrid orientation SOI and channel stress and a preparation method thereof.

2. Description of Related Arts

High-voltage devices and high-voltage integration processes are widely used and in heavy demand in the fields such as automotive electronics, LED driving circuits, and PDP driving. BCD process is the most mainstream high-voltage integration process, where laterally diffused metal oxide semiconductor (LDMOS) is a common integrated high-voltage device. In this kind of technologies, bulk silicon and SOI substrate materials are usually used, and in processes using voltages higher than 100 V, SOI substrate materials are usually used to solve the problem of isolation. People give more attention to N-LDMOS. However, similar to an MOS device, P-LDMOS is also an important part in a high-voltage MOS device and plays an important role in the fields such as PDP driving. Currently, compared with the N-LDMOS, the P-LDMOS has a higher Rdson which is twice or more than that in the N-LDMOS under the same breakdown voltage (BV). This is mainly caused by constraint of the hole mobility, in which an Ion of the P-LDMOS is smaller than that of the N-LDMOS. Therefore, it is desired to provide a new substrate material and introduce the channel stress, so as to improve a carrier mobility, reduce Rdson of the device, and improve performance of the device, thereby facilitating further improvement of integration and reduction of power consumption.

### SUMMARY OF THE PRESENT INVENTION

In view of the foregoing defects of the prior art, an objective of the present invention is to provide a preparation method of a device system structure based on hybrid orientation SOI and channel stress, so as to prepare an N-type high-voltage device and/or a low-voltage device and a P-type high-voltage device structure.

The objective of the present invention is to provide a device system structure based on hybrid orientation SOI and channel stress, so as to improve a carrier mobility of a device and reduce Rdson of a high-voltage device.

To achieve the foregoing objective and other related objectives, the present invention provides a preparation method of a device system structure based on hybrid orientation SOI and channel stress, at least including:

1) preparing a (100)/(110) global hybrid orientation SOI structure;

2) epitaxially growing a relaxed silicon-germanium layer and a strained silicon layer sequentially on the global hybrid orientation SOI structure;

3) forming an (110) epitaxial pattern window on the structure having the relaxed silicon-germanium layer and the strained silicon layer;

4) selectively epitaxially growing a (110) silicon layer and a non-relaxed silicon-germanium layer sequentially at the (110) epitaxial pattern window, and planarizing a surface of the patterned hybrid orientation SOI structure having the silicon-germanium layer epitaxially grown;

5) forming an isolation structure for isolating devices on the patterned hybrid orientation SOI structure having the silicon-germanium layer epitaxially grown; and

6) preparing a P-type high-voltage device structure in a (110) substrate portion of the global hybrid orientation SOI structure with the isolation structure, preparing an N-type high-voltage device structure and/or low-voltage device structures in the (100) substrate portion, and removing silicon-germanium and strained silicon in a drift region and a drain region of the N-type high-voltage device structure as well as silicon-germanium in a drift region and a drain region of the P-type high-voltage device structure.

The present invention further provides another preparation method of a device system structure based on hybrid orientation SOI and channel stress, at least including:

1) preparing a (110)/(100) global hybrid orientation SOI structure;

2) epitaxially growing a non-relaxed silicon-germanium layer on the global hybrid orientation SOI structure;

3) forming an (100) epitaxial pattern window on the non-relaxed silicon-germanium layer;

4) selectively epitaxially growing a relaxed silicon-germanium layer and a strained silicon layer sequentially at the (100) epitaxial pattern window, and planarizing a surface of the patterned hybrid orientation SOI structure having the strained silicon layer epitaxially grown;

5) forming an isolation structure for isolating devices on the patterned hybrid orientation SOI structure having the strained silicon layer epitaxially grown; and

6) preparing a P-type high-voltage device structure in a (110) substrate portion of the patterned hybrid orientation SOI structure with the isolation structure, preparing an N-type high-voltage device structure and/or low-voltage device structure in the (100) substrate portion, and removing silicon-germanium and strained silicon in a drift region and a drain region of the N-type high-voltage device structure as well as silicon-germanium in a drift region and a drain region of the P-type high-voltage device structure.

The present invention provides a device system structure based on hybrid orientation SOI and channel stress, at least including:

a P-type high-voltage device structure which is formed on a (110) substrate portion of a (100)/(110) hybrid orientation SOI structure and has a silicon-germanium channel;

an N-type high-voltage device structure and/or low-voltage device structures formed on the (100) substrate portion of the (100)/(110) hybrid orientation SOI structure and has a strained silicon channel; and

an isolation structure for isolating devices.

The present invention further provides a device system structure based on hybrid orientation SOI and channel stress, at least including:

a P-type high-voltage device structure which is formed on a (110) substrate portion of a (110)/(100) hybrid orientation SOI structure and has a silicon-germanium channel;

an N-type high-voltage device structure and/or low-voltage device structures formed on the (100) substrate portion of the (110)/(100) hybrid orientation SOI structure and has a strained silicon channel; and

an isolation structure for isolating devices.

As described above, the present invention has the following beneficial effects: effectively improving a carrier mobility, reducing Rdson of a device, improving performance of the device, and thereby facilitating further improvement of integration and reduction of power consumption.

### BRIEF DESCRIPTION OF THE DRAWINGS

FIG. 1 to FIG. 6 are flowcharts of a preparation method of a device system structure based on hybrid orientation SOI and channel stress according to the present invention.

FIG. 7 to FIG. 12 are flowcharts of another preparation method of a device system structure based on hybrid orientation SOI and channel stress according to the present invention.

FIG. 13 is a schematic diagram of the electron mobility and the hole mobility.

FIG. 14a to FIG. 14e are schematic diagrams of shapes of a channel structure contained in a high-voltage device.

### DETAILED DESCRIPTION OF THE PREFERRED EMBODIMENTS

Implementations of the present invention are described through specific embodiments, and persons skilled in the art may easily learn other advantages and effects of the present invention through content disclosed in the specification.

Reference is made to FIGS. 1 to 14e. It should be noted that structures, proportions, sizes and others illustrated in the accompanying drawings of the specification are merely for supporting the content disclosed in the specification to help persons skilled in the art to learn and read, and are not restriction conditions used to limit the implementation of the present invention and therefore do not have substantial technical meanings Any structure modification, proportional relationship change or size adjustment still falls within the scope covered by the technical content disclosed in the present invention, as long as the modification, change or adjustment does not affect the effects which may be produced in the present invention or objectives which may be achieved in the present invention. Meanwhile, words cited in the specification, such as “above”, “below”, “left”, “right”, “middle”, and “one”, are merely for explicit description, and are not intended to limit the implementation scope of the present invention. The change or adjustment of the relative relationships among them may also be considered as in the implementation scope of the present invention, if the technical content is not changed substantially.

### Embodiment 1

As shown in a figure, the present invention provides a preparation method of a device system structure based on hybrid orientation SOI and channel stress, including the following steps:

Step 1: Prepare a (100)/(110) global hybrid orientation SOI structure. For example, the (100)/(110) global hybrid orientation SOI structure is prepared by using a conventional process. As shown in FIG. 1, the (100)/(110) global hybrid orientation SOI structure includes a (100) silicon substrate, a buried oxide layer, and a (110) top silicon.

Step 2: Epitaxially grow a relaxed silicon-germanium layer and a strained silicon layer sequentially on the global hybrid orientation SOI structure. For example, as shown in FIG. 2, the relaxed silicon-germanium layer and the strained silicon layer are epitaxially grown sequentially on the global hybrid orientation SOI structure shown in FIG. 1.

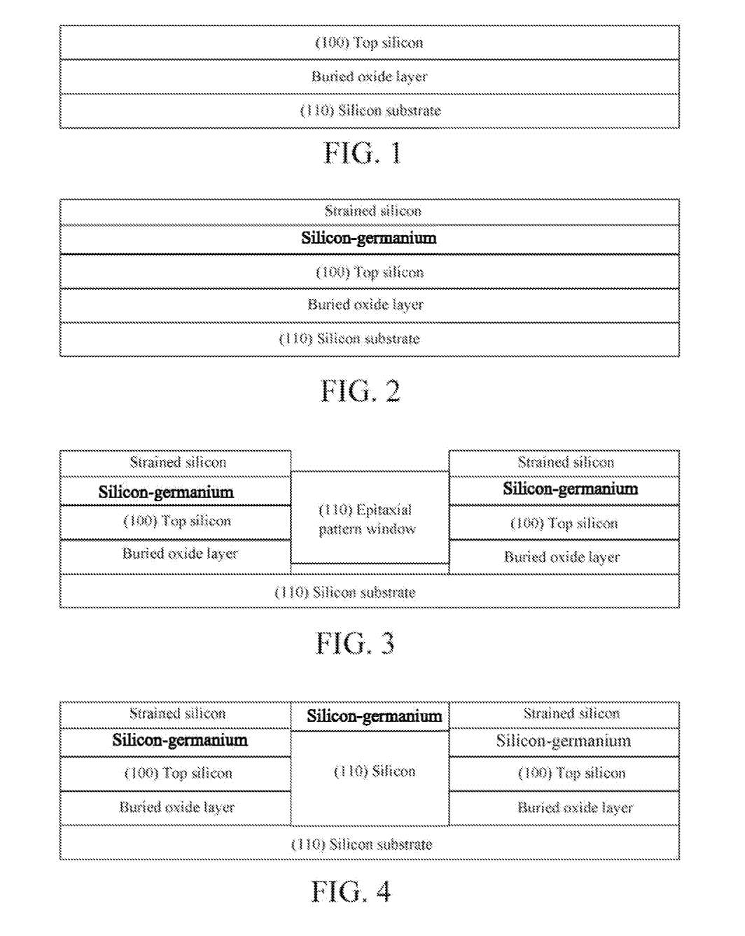

Step 3: Form an (110) epitaxial pattern window on the structure having the relaxed silicon-germanium layer and the strained silicon layer. For example, as shown in FIG. 3, on the global hybrid orientation SOI structure shown in FIG. 2, a process such as photo-lithography and etching is used to prepare the (100) epitaxial pattern window used to epitaxially grow (110) silicon, and an SiN Spacer protection structure is formed on a spacer of the pattern window.

Step 4: Selectively epitaxially grow a (110) silicon layer and a non-relaxed silicon-germanium layer sequentially at the (110) epitaxial pattern window, and planarize a surface of the patterned hybrid orientation SOI structure having the silicon-germanium layer epitaxially grown. As shown in FIG. 4, the (110) silicon and 10%˜20% silicon-germanium are selectively epitaxially grown sequentially at the (110) epitaxial pattern window, the thickness of the silicon-germanium is controlled to make it not relaxed, and the surface of the patterned hybrid orientation SOI structure after the epitaxially growth is planarized by chemical mechanical polishing (CMP).

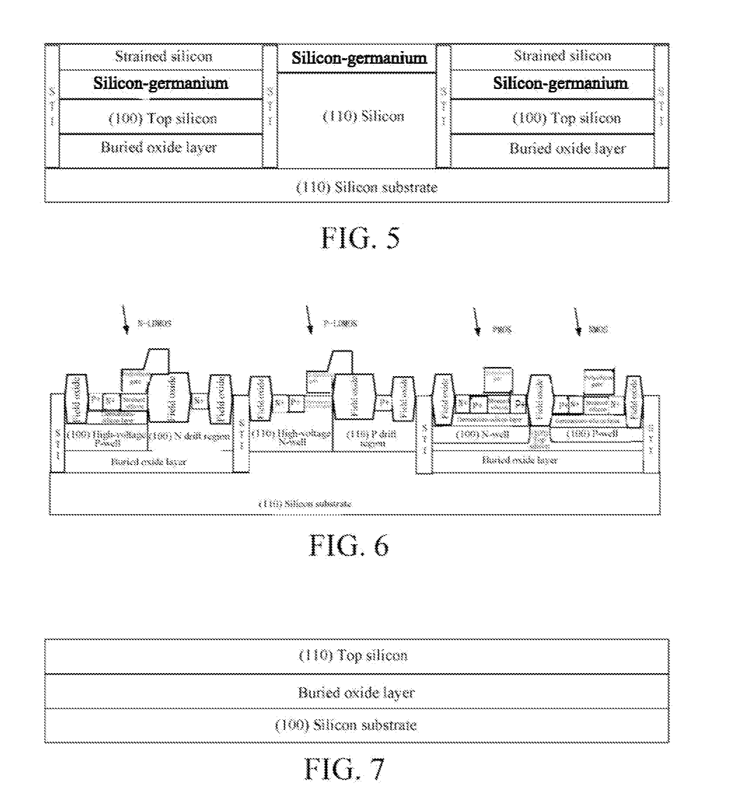

Step 5: Form an isolation structure for isolating devices on the patterned hybrid orientation SOI structure having the silicon-germanium layer epitaxially grown. For example, as shown in FIG. 5, an STI isolation trench is formed on the structure having the silicon-germanium layer epitaxially grown, and silicon dioxide is filled into the trench and a shallow trench isolation (STI) structure is formed by CMP.

Step 6: Prepare a P-type high-voltage device structure in a (110) substrate portion of the patterned hybrid orientation SOI structure with the isolation structure, prepare an N-type high-voltage device structure and/or low-voltage device structures in the (100) substrate portion, and remove silicon-germanium and strained silicon in a drift region and a drain region of the N-type high-voltage device structure as well as silicon-germanium in a drift region and a drain region of the P-type high-voltage device structure.

For example, as shown in FIG. 6, by using a BCD process, a P-LDMOS is prepared in the (110) substrate portion of the global hybrid orientation SOI structure with the isolation structure, an N-LDMOS as well as a low-voltage NMOS and PMOS are prepared in the (100) substrate portion, and silicon-germanium and strained silicon in the drift region and the drain region of the N-LDMOS as well as silicon-germanium in the drift region and the drain region of the P-LDMOS are removed.

Preferably, recess LOCOS process is used to remove silicon-germanium and strained silicon in the drift region and the drain region of the N-LDMOS as well as silicon-germanium in the drift region and the drain region of the P-LDMOS.

It should be noted that technical persons skilled in the art should understand that an isolation structure among low-voltage device structures may use one or both of the LOCOS isolation structure and the STI isolation structure when multiple low-voltage device structures exist, which is not described in detail herein.

Based on the foregoing preparation method, the prepared device system structure based on the hybrid orientation SOI and channel stress is shown in FIG. 6. The device system structure based on the hybrid orientation SOI and channel stress includes: a P-type high-voltage device structure which is formed on the (110) substrate portion of the (100)/(110) hybrid orientation SOI structure and has a silicon-germanium channel, for example, P-LDMOS; an N-type high-voltage device structure which is formed on the (100) substrate portion of the (100)/(110) hybrid orientation SOI structure and has a strained silicon channel, such as N-LDMOS; a low-voltage device structure which is formed on the (100) substrate portion of the (100)/(110) hybrid orientation SOI structure and has a strained silicon channel, for example, a low-voltage NMOS and PMOS; and an isolation structure for isolating devices, for example, an STI isolation trench.

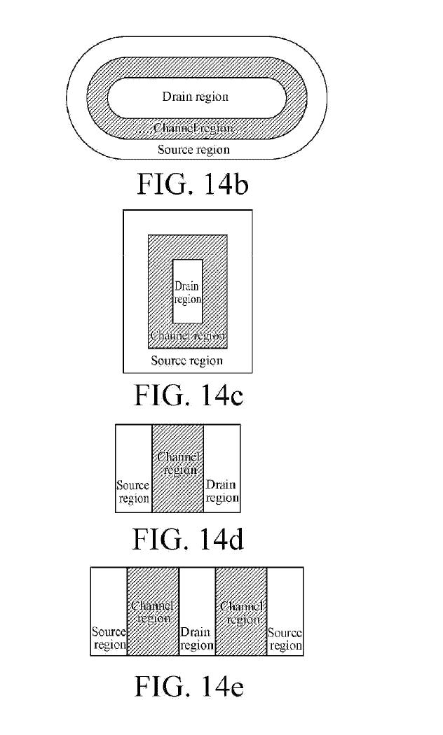

Preferably, the structure of the channel contained in the prepared P-type or N-type high-voltage device may be circular ring shaped (as shown in FIG. 14a), racetrack ring shaped (as shown in 14b), rectangular ring shaped (as shown in FIG. 14c), or straight strip shaped (as shown in FIGS. 14d and 14e) and so on. More preferably, a straight track portion of the straight strip shaped channel and/or the ring shaped channel of the P-type high-voltage device on the (110) silicon substrate follows along the <110> orientation.

### Embodiment 2

A shown in a figure, the present invention provides another preparation method of a device system structure based on hybrid orientation SOI and channel stress, including the following steps:

Step 1: Prepare a (110)/(100) hybrid orientation SOI structure. For example, the (110)/(100) global hybrid orientation SOI structure is prepared by using a conventional process. As shown in FIG. 7, the (110)/(100) global hybrid orientation SOI structure includes a (100) silicon substrate, a buried oxide layer, and a (110) top silicon.

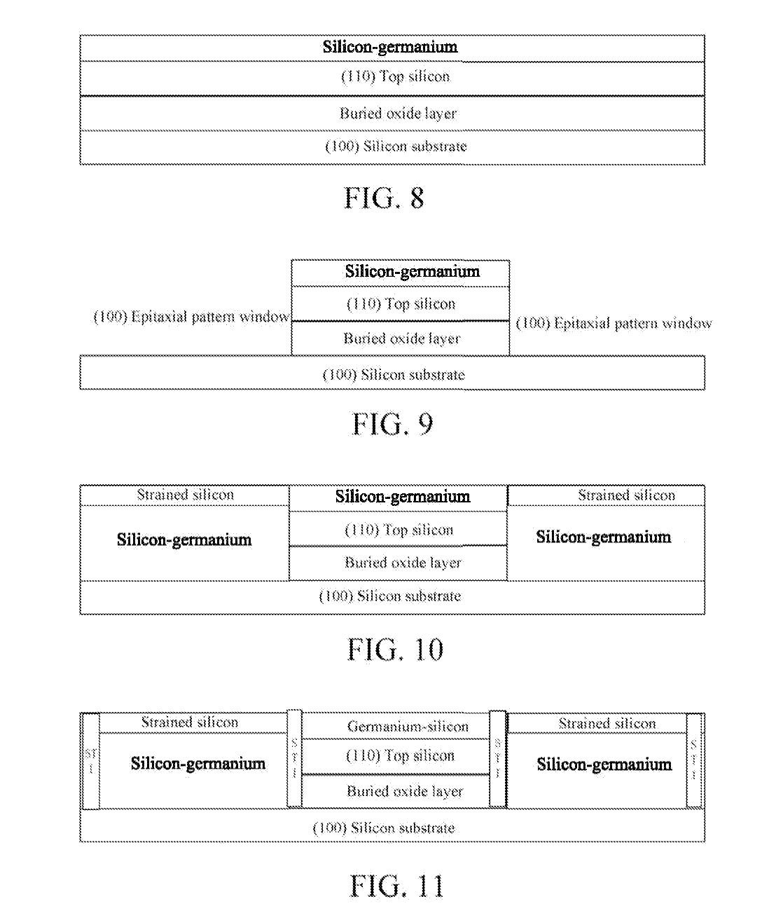

Step 2: Epitaxially grow a non-relaxed silicon-germanium layer on the global hybrid orientation SOI structure. For example, as shown in FIG. 8, the non-relaxed silicon-germanium layer is epitaxially grown on the global hybrid orientation SOI structure shown in FIG. 7.

Step 3: Form an (100) epitaxial pattern window on the non-relaxed silicon-germanium layer. For example, as shown in FIG. 9, on the global hybrid orientation SOI structure shown in FIG. 8, a process such as photo-lithography and etching is used to prepare the (100) epitaxial pattern window used to epitaxially grow (100) silicon, and an SiN Spacer protection structure is formed on a spacer of the pattern window.

Step 4: Selectively epitaxially grow a relaxed silicon-germanium layer and strained silicon layer sequentially at the (100) epitaxial pattern window, and planarize a surface of the patterned hybrid orientation SOI structure having the strained silicon layer epitaxially grown. As shown in FIG. 10, the relaxed silicon-germanium layer and the strained silicon layer are epitaxially grown at the (100) epitaxial pattern window, and the surface of the patterned hybrid orientation SOI structure after the epitaxially growth is planarized by chemical mechanical polishing (CMP).

Step 5: Form an isolation structure for isolating devices on the patterned hybrid orientation SOI structure having the strained silicon layer epitaxially grown. For example, as shown in FIG. 11, an STI isolation trench is formed on the structure having the strained silicon layer epitaxially grown, and silicon dioxide is filled into the trench and a shallow trench isolation (STI) structure is formed by CMP.

Step 6: Prepare a P-type high-voltage device structure in a (110) substrate portion of the patterned hybrid orientation SOI structure with the isolation structure, prepare an N-type high-voltage device structure and/or low-voltage device structures in the (100) substrate portion, and remove silicon-germanium and strained silicon in a drift region and a drain region of the N-type high-voltage device structure as well as silicon-germanium in a drift region and a drain region of the P-type high-voltage device structure.

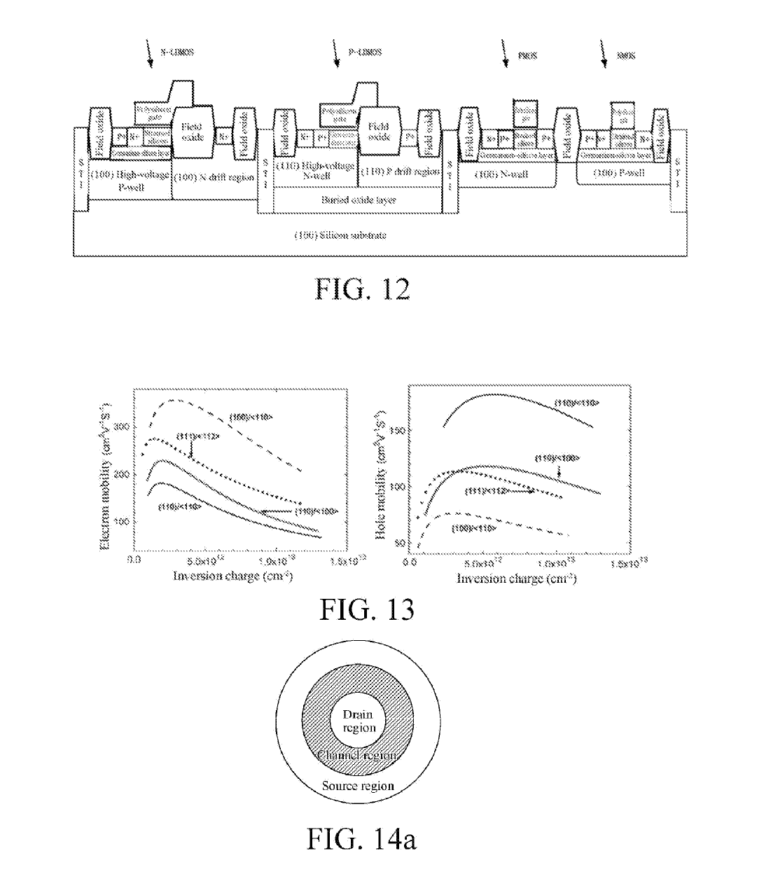

For example, as shown in FIG. 12, by using a BCD process, a P-LDMOS is prepared in the (110) substrate portion of the global hybrid orientation SOI structure with the isolation structure, an N-LDMOS as well as a low-voltage NMOS and PMOS are prepared in the (100) substrate portion, and silicon-germanium and strained silicon in the drift region and the drain region of the N-LDMOS as well as silicon-germanium in the drift region and the drain region of the P-LDMOS are removed.

It should be noted that technical persons skilled in the art should understand that an isolation structure among low-voltage device structures may use one or both of the LOCOS isolation structure and the STI isolation structure when multiple low-voltage device structures exist, which is not described in detail herein.

Based on the foregoing preparation method, the prepared device system structure based on the hybrid orientation SOI and channel stress is shown in FIG. 12. The device system structure based on the hybrid orientation SOI and channel stress includes: a P-type high-voltage device structure which is formed on the (110) substrate portion of the (110)/(100) hybrid orientation SOI structure and has a silicon-germanium channel, for example, P-LDMOS; an N-type high-voltage device structure which is formed on the (100) substrate portion of the (110)/(100) global hybrid orientation SOI structure and has a strained silicon channel, such as N-LDMOS; a low-voltage device structure which is formed on the (100) substrate portion of the (110)/(100) hybrid orientation SOI structure and has a strained silicon channel, for example, a low-voltage NMOS and PMOS; and an isolation structure for isolating devices, for example, an STI isolation trench.

Preferably, the structure contained in the prepared P-type or N-type high-voltage device may be circular ring shaped (as shown in FIG. 14a), racetrack ring shaped (as shown in 14b), rectangular ring shaped (as shown in FIG. 14c), or straight strip shaped (as shown in FIGS. 14d and 14e) and so on. More preferably, a straight track portion of the straight strip shaped channel and/or the ring shaped channel of the P-type high-voltage device on the (110) silicon substrate follows along the <110> orientation.

Therefore, the preparation method of the device system structure based on hybrid orientation SOI and channel stress is based on the greatest electron mobility of the (100) silicon substrate in the <110> orientation. The (110) silicon substrate has the greatest hole mobility in the <110> orientation, and the hole mobility of the (110) silicon substrate is more than twice of that of the (100) silicon substrate; meanwhile, the hole mobility of the silicon substrate (110) in the <100> orientation is improved significantly, as shown specifically in FIG. 13. Therefore, in the present invention, an N-type high-voltage device is prepared on the (100) substrate, a P-type high-voltage device is prepared at the (110) substrate, and low-voltage devices are also prepared on the (100) substrate, thereby being compatible with the existing BCD process; in this manner, the existing BCD process may be transferred directly in the subsequent procedure, so as to easily achieve the objectives of industrialization and practical application. In addition, by using silicon-germanium and/or strained silicon materials, stress is introduced to a channel of the N-LDMOS and PLDMOS and a channel of the low-voltage device. Under the premise that the breakdown voltage is unchanged, the carrier mobility is further improved, so that Rdson of the N-LDMOS and P-LDMOS is further reduced. Compared with the existing P-LDMOS prepared on the (100) substrate, by using the high-voltage integration technology implemented through the hybrid orientation SOI, Rdson of the P-LDMOS is reduced to at least a half. In addition, no buried oxide layer exists in the (110) substrate portion in Embodiment 1, so the self-heating effect and back-gate effect of the P-LDMOS may be reduced; and no buried oxide layer exists in the (100) substrate portion in Embodiment 2, so the self-heating effect and back-gate effect of the N-LDMOS may be reduced.

In addition, it should be noted that, persons skilled in the art may understand that the foregoing embodiments are merely listed as examples and are not intended to limit the present invention. In fact, the prepared device system structure may include one or several of a P-type high-voltage device, an N-type high-voltage device, a P-type low-voltage device, and an N-type low-voltage device, which is not described in detail herein.

To sum up, the preparation method of the device system structure based on hybrid orientation SOI and channel stress according to the present invention is used to prepare P-type/N-type high-voltage and/or low-voltage devices, based on hybrid orientation SOI and channel stress. The present invention effectively improves the carrier mobility, reduces Rdson of the device, improves performance of the devices, and facilitates further improvement of integration and reduction of power consumption. Therefore, the present invention effectively overcomes various defects in the prior art and provides a high industrial utilization value.

The foregoing embodiments are merely used as examples to describe the principles and effects of the present invention, and are not intended to limit the present invention. Any person familiar with the technology may modify or change the foregoing embodiments, without departing from the spirit and scope of the present invention. Therefore, any equivalent modification or change made by any person having common knowledge in the technical field, without departing from the spirit and technical thoughts of the present invention, should still be covered by the claims of the present invention.

What is claimed is:

1. A preparation method of a device system structure based on hybrid orientation SOI and channel stress, at least comprising:
a) preparing a (100)/(110) global hybrid orientation SOI structure;
b) epitaxially growing a relaxed silicon-germanium layer and strained silicon layer sequentially on the global hybrid orientation SOI structure;
c) forming an (110) epitaxial pattern window on the structure having the relaxed silicon-germanium layer and the strained silicon layer;
d) selectively epitaxially growing a (110) silicon layer and a non-relaxed silicon-germanium layer sequentially at the (110) epitaxial pattern window, and planarizing a surface of the patterned hybrid orientation SOI structure having the silicon-germanium layer epitaxially grown;
e) forming an isolation structure for isolating devices on the patterned hybrid orientation SOI structure having the silicon-germanium layer epitaxially grown; and
f) preparing a P-type high-voltage device structure in a (110) substrate portion of the patterned hybrid orientation SOI structure with the isolation structure, preparing an N-type high-voltage device structure and/or low-voltage device structures in the (100) substrate portion, and removing silicon-germanium and strained silicon in a drift region and a drain region of the N-type high-voltage device structure as well as silicon-germanium in a drift region and a drain region of the P-type high-voltage device structure.

2. The preparation method of the device system structure based on hybrid orientation SOI and channel stress as in claim 1, wherein a local oxidation of silicon (LOCOS) process is used to remove the silicon-germanium and the strained silicon in the drift region and the drain region of the N-type high-voltage device structure as well as the silicon-germanium in the drift region and the drain region of the P-type high-voltage device structure.

3. The preparation method of the device system structure based on hybrid orientation SOI and channel stress as in claim 1, wherein isolation structures among the low-voltage device structures comprise an LOCOS isolation structure and/or an STI isolation structure when multiple low-voltage device structures exist.

4. The preparation method of the device system structure based on hybrid orientation SOI and channel stress as in claim 1, wherein both the isolation structure between the high-voltage devices and the isolation structure between the high-voltage device and the low-voltage device comprise the STI isolation structure.

5. A device system structure based on hybrid orientation SOI and channel stress, at least comprising:
a P-type high-voltage device structure which is formed in a (110) substrate portion of a (100)/(110) hybrid orientation SOI structure and comprises a silicon-germanium channel;
an N-type high-voltage device structure and/or low-voltage device structures formed in the (100) substrate portion of the (100)/(110) hybrid orientation SOI structure and comprises a strained silicon channel; and
an isolation structure for isolating devices.

6. The device system structure based on hybrid orientation SOI and channel stress as in claim 5, wherein isolation structures among low-voltage devices comprise an LOCOS isolation structure and/or an STI isolation structure when multiple low-voltage device structures exist.

7. The device system structure based on hybrid orientation SOI and channel stress as in claim 5, wherein both the isolation structure between the high-voltage devices and the isolation structure between the high-voltage device and the low-voltage device comprise the STI isolation structure.

8. The device system structure based on hybrid orientation SOI and channel stress as in claim 5, wherein a structure of a channel contained in a high-voltage device comprises at least one of: a circular ring shaped channel structure, a racetrack ring shaped channel structure, a rectangular ring shaped channel structure, and a straight strip shaped channel structure.

9. The device system structure based on hybrid orientation SOI and channel stress as in claim 8, wherein the straight strip shaped channel structure and/or the straight track portion of the ring shaped channel of the P-type high-voltage device on the (110) silicon substrate follows along the <110> orientation.

10. A preparation method of a device system structure based on hybrid orientation SOI and channel stress, at least comprising:
a) preparing a (110)/(100) global hybrid orientation SOI structure;
b) epitaxially growing a non-relaxed silicon-germanium layer on the global hybrid orientation SOI structure;
c) forming an (100) epitaxial pattern window on the non-relaxed silicon-germanium layer;
d) selectively epitaxially growing a relaxed silicon-germanium layer and strained silicon layer sequentially at the (100) epitaxial pattern window, and planarizing a surface of the patterned hybrid orientation SOI structure having the strained silicon layer epitaxially grown;
e) forming an isolation structure for isolating devices on the patterned hybrid orientation SOI structure having the strained silicon layer epitaxially grown; and
f) preparing a P-type high-voltage device structure in a (110) substrate portion of the patterned hybrid orientation SOI structure with the isolation structure, preparing an N-type high-voltage device structure and/or low-voltage device structures in the (100) substrate portion, and removing silicon-germanium and strained silicon in a drift region and a drain region of the N-type high-voltage device structure as well as silicon-germanium in a drift region and a drain region of the P-type high-voltage device structure.

11. The preparation method of the device system structure based on hybrid orientation SOI and channel stress as in claim 10, wherein a local oxidation of silicon (LOCOS) process is used to remove the silicon-germanium and the strained silicon in the drift region and the drain region of the N-type high-voltage device structure as well as the silicon-germanium in the drift region and the drain region of the P-type high-voltage device structure.

12. The preparation method of the device system structure based on hybrid orientation SOI and channel stress as in claim 10, wherein isolation structures among the low-voltage device structures comprise an LOCOS isolation structure and/or an STI isolation structure when multiple low-voltage device structures exist.

13. The preparation method of the device system structure based on hybrid orientation SOI and channel stress as in claim 10, wherein both the isolation structure between the high-voltage devices and the isolation structure between the high-voltage device and the low-voltage device comprise the STI isolation structure.

14. A device system structure based on hybrid orientation SOI and channel stress, at least comprising:
a P-type high-voltage device structure which is formed on a (110) substrate portion of a (110)/(100) hybrid orientation SOI structure and comprises a silicon-germanium channel;
an N-type high-voltage device structure and/or low-voltage device structures formed on the (100) substrate portion of the (110)/(100) hybrid orientation SOI structure and comprises a strained silicon channel; and
an isolation structure for isolating devices.

15. The device system structure based on hybrid orientation SOI and channel stress as in claim 14, wherein isolation structures among low-voltage device structures comprise an LOCOS isolation structure and/or an STI isolation structure when multiple low-voltage device structures exist.

16. The device system structure based on hybrid orientation SOI and channel stress as in claim 14, wherein both the isolation structure between the high-voltage devices and the isolation structure between the high-voltage device and the low-voltage device comprise the STI isolation structure.

17. The device system structure based on hybrid orientation SOI and channel stress as in claim 14, wherein a structure of a channel contained in a high-voltage device comprises at least one of: a circular ring shaped channel structure, a racetrack ring shaped channel structure, a rectangular ring shaped channel structure, and a straight strip shaped channel structure.

18. The device system structure based on hybrid orientation SOI and channel stress as in claim 17, wherein the straight strip shaped channel structure and/or the straight track portion of the ring shaped channel of the P-type high-voltage device on the (110) silicon substrate follows along the <110> orientation.
